(19) United States
(12) Patent Application Publication
(10) Pub. No.: US 2004/0163029 A1
(43) Pub. Date: Aug. 19, 2004

(54) Data recovery techniques in storage systems

(75) Inventors: Matthew J. Foley, Santa Clara, CA (US); Lewis Kawecki, Kings Beach, CA (US); Nam Le, San Jose, CA (US); Rony Yakir, Mountain View, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Arkivio, Inc., Mountain View, CA

(21) Appl. No.: 10/726,007

(22) Filed: Dec. 1, 2003

Related U.S. Application Data
(60) Provisional application No. 60/430,464, filed on Dec. 2, 2002.

(51) Int. Cl. G11C 29/00

(52) U.S. Cl. 714/769

(57) ABSTRACT

Techniques for maintaining data consistency in a storage environment. In a HSM controlled storage environment, techniques are provided for automatically detecting and correcting inconsistencies after a file system or a portion thereof has been restored from backup. The file system may store data files, tag files, and/or repository files that have been restored from backup.

### CROSS-REFERENCES TO RELATED APPLICATIONS

The present application claims priority from and is a non-provisional of U.S. Provisional Application No. 60/430,464, filed Dec. 2, 2002, the entire contents of which are herein incorporated by reference for all purposes.

### BACKGROUND OF THE INVENTION

The present relates generally to the field of data storage and management, and more particularly to techniques for maintaining consistency of data in a file system after the file system or portions of the file system have been restored from backup.

In a typical storage environment comprising multiple servers coupled to one or more storage units, an administrator administering the environment has to perform several tasks to ensure availability and efficient accessibility of data. Traditionally, these tasks were performed manually by the storage administrator.

More recently, storage management applications are available that attempt to automate some of the manual tasks. For example, Hierarchical Storage Management (HSM) applications are used to migrate data among a hierarchy of storage devices. For example, files may be migrated from online storage to near-online storage, from near-online storage to offline storage, and the like, to manage storage utilization. When a file is migrated from its originating storage location to another storage location (referred to as the “repository storage location”), a stub file or tag file is left in place of the migrated file in the originating storage location.

The tag file stores information that can be used to locate the migrated data. For example, the tag file comprises information that allows a HSM application to locate the migrated data in the repository storage location. The tag file may contain attributes or metadata of the migrated file. For example, the tag file can contain a file name or file identifier that allows the management system to find the necessary information (from a database or from the tag file itself) to recall the file. In certain embodiments, the information that is used to locate the migrated file may also be stored in a database rather than in the tag file, or in addition to the tag file. The migrated file may be remigrated from the repository storage location to another repository storage location. The tag file information is updated to point to the location of the migrated or remigrated data.

The tag file serves as an entity in the file system through which a user or application can access the original data file. By using a tag file, the migration of the data is made transparent to the users of the data. Users and applications can access the migrated file as though the file was still stored in the originating storage location. When a HSM application receives a request to access a migrated file, the HSM application determines the repository storage location of the migrated data using information stored in the tag file or some database and recalls the requested data file from the repository storage location back to the originating storage location.

Storage systems are also prone to crashes that may result in loss of data. In order to minimize data loss, backups of the file system are usually taken and used for restoring data after a crash. For example, if a data storage device such as a hard drive crashes on a computer running HSM resulting in partial or complete loss of data on the drive, the data can be restored from an archive such as backup tape. However, changes to the data that may have occurred after the backup and prior to the crash. As a result, the data restored from backup may be inconsistent with other data in the HSM file system. For example: tag files included in the data restored from the backup medium may no longer be valid due to changes that may have occurred in the HSM data; a data file represented by a tag file may have been remigrated to another location after the backup and before the crash; the data file may have been modified (e.g., changes to data content, size of data, and access dates) after the backup; a data file may have been migrated at the time of the backup but may have been recalled before the crash and as a result the tag file restored from backup may no longer have any validity; etc. Several other types of changes may have altered the state of the files after the backup was performed. As a result, the restored data may be inconsistent with other data in the storage environment.

Conventionally, after data has been restored from backup, a person (e.g., a storage system administrator) restoring the backed up data has to manually verify consistency of the restored data. For example, the system administrator has to test each tag file manually to verify if it points to a valid data file. The administrator also has to manually perform operations to remove the detected inconsistencies. For example, some tag files may be invalid and need to be deleted, while others may no longer point to the correct data location. As a result, some data files may need to be moved manually from their remote locations to the originating computer (replacing the incorrect tag file).

In addition to HSM tag files and data files, a computer server may also store the data content (referred to as repository files) of files that have been migrated from other servers. After a crash, the restored repository files also have to be manually verified to see if they are still valid. If invalid repository files are not removed (cleaned up), they continue to sit on the hard disk and waste storage space. Other corrections may also be required to enforce consistency and minimize data loss. Conventionally, a storage administrator has to manually perform these tasks.

In conventional systems, the only alternative to all the manual work described above is to recall all the HSM managed files every time the data is backed up. This however would put a tremendous strain on the network and limit the advantages of using HSM in the first place. Furthermore, all the recalled HSM data files may not fit on the originating computer at the same time, thereby making the procedure unfeasible and impractical in many storage environments.

### BRIEF SUMMARY OF THE INVENTION

Embodiments of the present invention provide techniques for maintaining data consistency in a storage environment. In a HSM controlled storage environment, techniques are provided for automatically detecting and resolving inconsistencies after a file system or a portion thereof has been restored from backup. The file system may store data files, tag files, and/or repository files that have been restored from backup.

According to an embodiment of the present invention, techniques are provided for maintaining consistency for a server in a storage environment comprising a plurality of servers, the plurality of servers including a first server having a file system storing a plurality of files restored from a backup medium, the plurality of files including one or more data files and one or more tag files corresponding to data files that have migrated from the file system. First information is provided comprising information related to the plurality of files stored in the file system of the first server, the first information comprising a plurality of entries, each entry corresponding to a file and storing status information identifying whether the file is a tag file or a data file, each entry storing attributes information identifying one or more attributes of the file. The plurality of files are compared to information included in the first information. Based upon the comparing, at least a first inconsistency is identified where information associated with a first file from the plurality of files is inconsistent with information in the first information. A first set of one or more operations are performed to resolve the first inconsistency.

According to another embodiment of the present invention, techniques are provided for maintaining consistency for a server in a storage environment comprising a plurality of servers, the plurality of servers including a first server having a file system storing a plurality of files restored from a backup medium, the plurality of files including one or more data files and one or more tag files corresponding to data files that have migrated from the file system. First information is provided including information related to files stored in the file system of the first server. Second information is provided comprising a plurality of entries, each entry storing information related a file stored by the plurality of servers that has been migrated. A first tag file from the plurality of files is compared to information stored in the second information. Based upon the comparison, at least a first inconsistency is identified where information associated with the first tag file is inconsistent with the information included in the second information. A first set of one or more actions are preformed to resolve the first inconsistency.

According to yet another embodiment of the present invention, techniques are provided for recovering information in a HSM environment comprising a plurality of servers, the plurality of servers including a first server having a file system storing a plurality of files including one or more data files and one or more tag files corresponding to data files that have migrated from the file system. In this embodiment, first information is provided including information related to one or more data files that have been migrated, wherein the information related to each data file that has been migrated includes information identifying a server and a volume from which the data file is migrated, and information identifying a server and volume where the migrated data of the data file is stored, the first information comprising information related to a first data file that has been migrated. Based upon the first information, determination is made that the file system does not contain a tag file corresponding to first data file. A tag file is created corresponding to the first data file based upon information included in the first information.

The foregoing, together with other features, embodiments, and advantages of the present invention, will become more apparent when referring to the following specification, claims, and accompanying drawings.

### BRIEF DESCRIPTION OF THE DRAWINGS

FIG. 1 is a simplified block diagram of a storage environment that may incorporate an embodiment of the present invention;

FIG. 2 is a simplified high-level flowchart depicting a method of detecting and correcting inconsistencies in a restored file system according to an embodiment of the present invention;

FIG. 3 is a simplified high-level flowchart depicting a method of detecting and correcting tag files and data files-related inconsistencies in a restored file system according to an embodiment of the present invention;

FIG. 4 is a simplified high-level flowchart depicting a method of comparing SDb tag file entries to files in the file system and taking appropriate actions to correct any detected inconsistencies according to an embodiment of the present invention;

FIG. 5 is a simplified high-level flowchart depicting a method of detecting and correcting tag files and data files related inconsistencies in a restored file system according to an embodiment of the present invention;

FIG. 6 is a simplified high-level flowchart depicting a method of comparing CDb entries to files in the restored file system and taking appropriate actions to correct the detected inconsistencies according to an embodiment of the present invention;

FIG. 7 is a simplified high-level flowchart depicting a method of processing repository files in the restored file system according to an embodiment of the present invention; and

FIG. 8 is a simplified block diagram of a computer system capable of implementing an embodiment of the present invention.

### DETAILED DESCRIPTION OF THE INVENTION

In the following description, for the purposes of explanation, specific details are set forth in order to provide a thorough understanding of the invention. However, it will be apparent that the invention may be practiced without these specific details.

### NOTATIONS

The following notations will be used in this application to facilitate discussion of migration and remigration operations according to an embodiment of the present invention. These notations are not intended to limit the scope of the present invention as recited in the claims.

(1) “Date file” is any ordinary file that may contain data provided by a user or application and which has not been migrated. When a data file is migrated from its originating location by an application such as an HSM application, a tag (or stub) file is left in place of the data file.

(2) A “tag file” or “stub file” is a physical file that represents a migrated file. When a data file is migrated from the data file's originating storage location, the tag file is stored in the originating storage location to represent the migrated data file. The tag file may store information that enables a migrated data file to be recalled. In one embodiment, the information stored in the physical tag file identifies the location of the migrated data. In another embodiment, information (e.g., a file identifier or file name) stored in the tag file may be used to find additional information, which may be stored in one or more databases, that is used to locate the migrated data and facilitate the recall operation. A tag file may also contain selected attributes and/or metadata related to the corresponding migrated data file. A portion of the data may also be stored in the tag file in one embodiment. The tag file serves as an entity in the file system through which the original migrated file can be accessed by users or applications.

(3) An “originating volume” is a volume where a data file is stored before it is migrated and where a tag file corresponding to the data file resides after the data file has been migrated.

(4) An “originating server” is a server configured to manage access to an originating volume. For example, an originating server is a server providing access to a volume where a data file is stored before it is migrated and where a substitute tag file corresponding to the data file resides when the data file is migrated. The data file or tag file may be considered as stored on the originating server.

(5) A “repository volume” is a volume that stores the migrated (or remigrated) data for a migrated data file. The migrated data is stored in a repository file on the repository volume.

(6) A “repository server” is a server which is configured to manage access to a repository volume. For example, a repository server is a server providing access to a volume where a repository file is stored. The repository file may be considered as stored on the repository server.

### SYSTEM DESCRIPTION

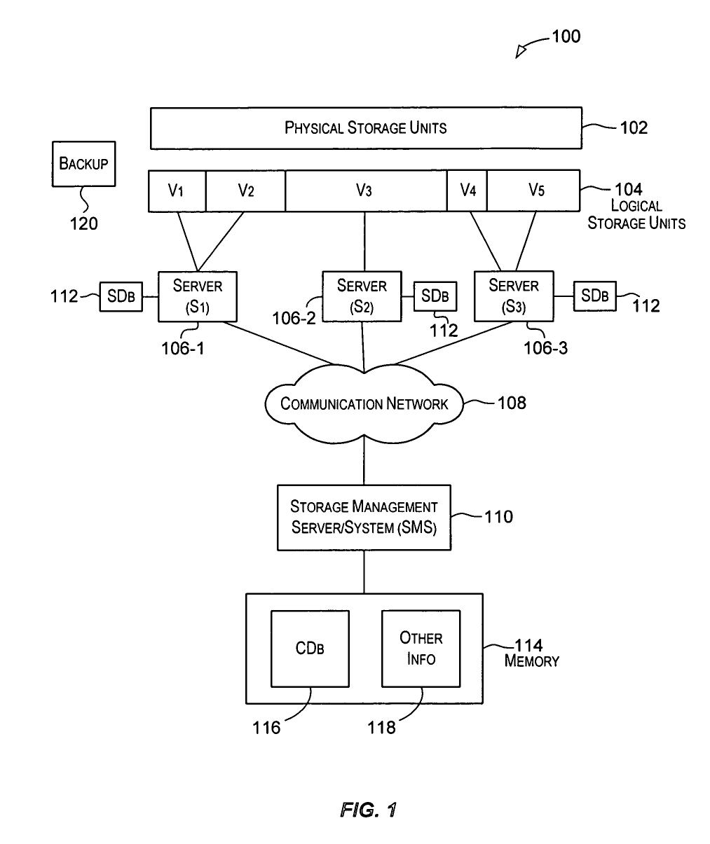

FIG. 1 is a simplified block diagram of a storage environment 100 that may incorporate an embodiment of the present invention. Storage environment 100 depicted in FIG. 1 is merely illustrative of an embodiment incorporating the present invention and does not limit the scope of the invention as recited in the claims. One of ordinary skill in the art would recognize other variations, modifications, and alternatives.

As depicted in FIG. 1, storage environment 100 comprises a plurality of physical storage devices 102 for storing data. Physical storage devices 102 may include disk drives, tapes, hard drives, optical disks, RAID storage structures, solid state storage devices, SAN storage devices, NAS storage devices, and other types of devices and storage media capable of storing data. The term “physical storage unit” is intended to refer to any physical device, system, etc. that is capable of storing information or data.

Physical storage units 102 may be organized into one or more logical storage units/devices 104 that provide a logical view of underlying disks provided by physical storage units 102. Each logical storage unit (e.g., a volume) is generally identifiable by a unique identifier (e.g., a number, name, etc.) that may be specified by the administrator. A single physical storage unit may be divided into several separately identifiable logical storage units. A single logical storage unit may span storage space provided by multiple physical storage units 102. A logical storage unit may reside on non-contiguous physical partitions. By using logical storage units, the physical storage units and the distribution of data across the physical storage units becomes transparent to servers and applications. For purposes of description and as depicted in FIG. 1, logical storage units 104 are considered to be in the form of volumes. However, other types of logical storage units are also within the scope of the present invention.

The term “storage unit” is intended to refer to a physical storage unit (e.g., a disk) or a logical storage unit (e.g., a volume).

Storage environment 100 comprises several servers 106 and 110. Servers 106 may be any data processing systems. One or more volumes from logical storage units 104 may be assigned or allocated to servers 106. For example, as depicted in FIG. 1, volumes V1 and V2 are assigned to server (S1) 106-1, volume V3 is assigned to server (S2) 106-2, and volumes V4 and V5 are assigned to server (S3) 106-3. A server 106 provides an access point for the one or more volumes allocated to that server.

The files stored on volumes assigned to a server are considered to be part of the file system of the server. A file system for a server may be spread across one or more volumes. The file system for a server may store data files (i.e., files that have not been migrated), tag files corresponding to data files that have been migrated from the server file system, and repository files corresponding to data migrated from other server file systems and stored on the server's file system. Accordingly, a particular server may function as an originating server for data files that have been migrated from the server's file system and a repository server for data migrated to the server's file system from other server file systems.

According to an embodiment of the present invention, as depicted in FIG. 1, information related to data files and tag files stored in the file system for the server may be stored in a database such as source database (“SDb”) 112 (also referred to as “file status database”) accessible to the server. SDb 112 may store an entry or record for each file in the file system. According to an embodiment of the present invention, an SDb entry for a file in the file system for a server may include: (1) a unique file identifier for the file (the unique identifier may be generated by the storage management software for newly created files or for preexisting files that do not already have a unique file identifier); (2) information identifying the directory in which the file is stored in the file system; (3) file status information indicating if the file is a data file or a tag file corresponding to a migrated data file; (4) file attributes information such as read/write permissions associated with the file, information identifying the creator or modifier of the file, dates and times (e.g., creation date and time, last modification date and time, date and time of access, etc.) associated with the file, file size information, filename, etc.; (5) if the file is a repository file, then information identifying the location where the file was migrated; and (6) other information. The information stored in the SDb for a server is updated as changes (files are created, modified, deleted, migrated, recalled, etc.) are made to the file system of the server. The SDb for a server may be stored on a volume coupled to the server or in some other remote location accessible to the server.

Servers 106 may be coupled to storage management server (SMS) either directly or via a communication network 108 as depicted in FIG. 1. Communication network 108 provides a mechanism for allowing communication between SMS 110 and servers 106. Communication network 108 may be a local area network (LAN), a wide area network (WAN), a wireless network, an Intranet, the Internet, a private network, a public network, a switched network, or any other suitable communication network. Communication network 108 may comprise many interconnected computer systems and communication links. The communication links may be hardwire links, optical links, satellite or other wireless communications links, wave propagation links, or any other mechanisms for communication of information. Various communication protocols may be used to facilitate communication of information via the communication links, including TCP/IP, HTTP protocols, extensible markup language (XML), wireless application protocol (WAP), Fiber Channel protocols, protocols under development by industry standard organizations, vendor-specific protocols, customized protocols, and others.

SMS 110 is configured to provide centralized storage management services for storage environment 100. According to an embodiment of the present invention, SMS 110 is configured to store data and provide services to enable HSM-related processing. For example, SMS 110 stores information that tracks locations of files that are migrated (or remigrated) and recalled. The information may be stored in memory and/or disk 114 accessible to SMS 110. For example, as shown in FIG. 1, memory and/or disk 114 may store a central database 116 (“CDb”) (also referred to as “Migrated Data Database”), and other information 118.

CDb 116 may store information related to files that have been migrated (or remigrated) in storage environment 100. For example, in one embodiment, for each migrated file, CDb 116 may store an entry or record comprising: (1) a machine identifier of the originating server for the file; (2) the file's unique identifier; (3) information identifying the originating (or source) volume for the file (e.g., a source volume identifier); (4) information identifying the repository volume where the repository file corresponding to the migrated file resides (e.g., a target volume identifier); (5) information identifying the repository server; (6) file status information; (7) file size information; and (8) other information. The information in CDb 116 is updated as files are migrated, remigrated, and recalled in the storage environment. Other information 118 may include: information related to storage policies and rules configured for the storage environment, information related to the various monitored storage units, etc.

SDb 112 and CDb 116 may be embodied in various forms including as a relational database, directory services, various data structure, etc. The information may be stored in various formats.

Information in SDb 112 and CDb 116 is updated when a migration operation is performed. In a migration operation, a data file (or a portion thereof) is moved from the originating volume allocated to an originating server to a repository storage location on a repository volume allocated to a repository server. A stub or tag file is left in place of the migrated data file on the originating volume. The tag file stores information that can be used to determine the identity and location of the repository volume and repository server. The tag file may comprise the meta-data portion of the migrated file and a file identifier for the migrated file. The tag file may also store a cache comprising a small portion of the data portion of the migrated data file. The tag file may also store information about the repository server. According to an embodiment of the present invention, a unique repository identifier (referred to as the URI) is generated and saved in the tag file. The URI may be a combination of the originating server identifier (e.g., machine ID for the originating server) and a unique file identifier for the migrated file. The URI facilitates identification of the repository server and volume for a migrated file. The URI and other information stored in a tag file may also be stored in SDb 112 and/or CDb 116.

During a remigration operation, repository data from a repository volume allocated to a repository server is moved to another volume allocated to another server. Information in SDb 112 and CDb 116 is updated to reflect the remigration operation.

A recall operation may be performed when a request is received to access a migrated data file. According to an embodiment of the present invention, in a recall operation, information in the tag file is used to access an entry in CDb 116 corresponding to the migrated file. The entry in the CDb 116 is used to identify the repository server and repository volume where the migrated data is stored. This information is then used to recall the migrated data from the repository volume back to the originating volume. The tag file corresponding to the recalled data file is deleted and replaced with the recalled data file. Information in SDb 112 and CDb 116 is updated to reflect the recall operation.

An unsynchronized recall occurs when a migrated file is recalled using information in the SDb rather than the CDb possibly because CDb 116 is not accessible. In this scenario, the file data is recalled using information stored in the SDb 112 of the originating server of the file. The information in the CDb 116 is updated (or synchronized) at a later time when it is accessible.

In most storage environments, backups are performed at regular intervals to minimize the possibility and extent of data loss. Typically, in a backup operation, information from file systems of the servers are backed up or archived to backup storage media 120 such as tapes. In the case of a sever crash or data storage device failure (e.g., a hard drive crash) resulting in partial or complete loss of data on the drive, the data for the server or device can be restored from backup media 120. However, changes may have occurred to the file systems after a backup and prior to the crash. For example: tag files included in the data restored from the backup medium may no longer be valid due to changes that may have occurred in the HSM data; a data file represented by a tag file may have been remigrated to another location after the backup and before the crash; the data file may have been modified (e.g., changes to data content, size of data, and access dates) after the backup; a data file may have been migrated at the time of the backup but may have been recalled before the crash and as a result the tag file restored from backup may no longer have any validity; etc. These changes that occur after data backup are not reflected in the backed up data and are thus not reflected in the restored data. As a result, inconsistencies may arise in information stored in the SDb 112 and CDb 116 and the files stored on the restored file system. Unless corrected, these inconsistencies can cause errors and severely hamper the performance of the storage environment.

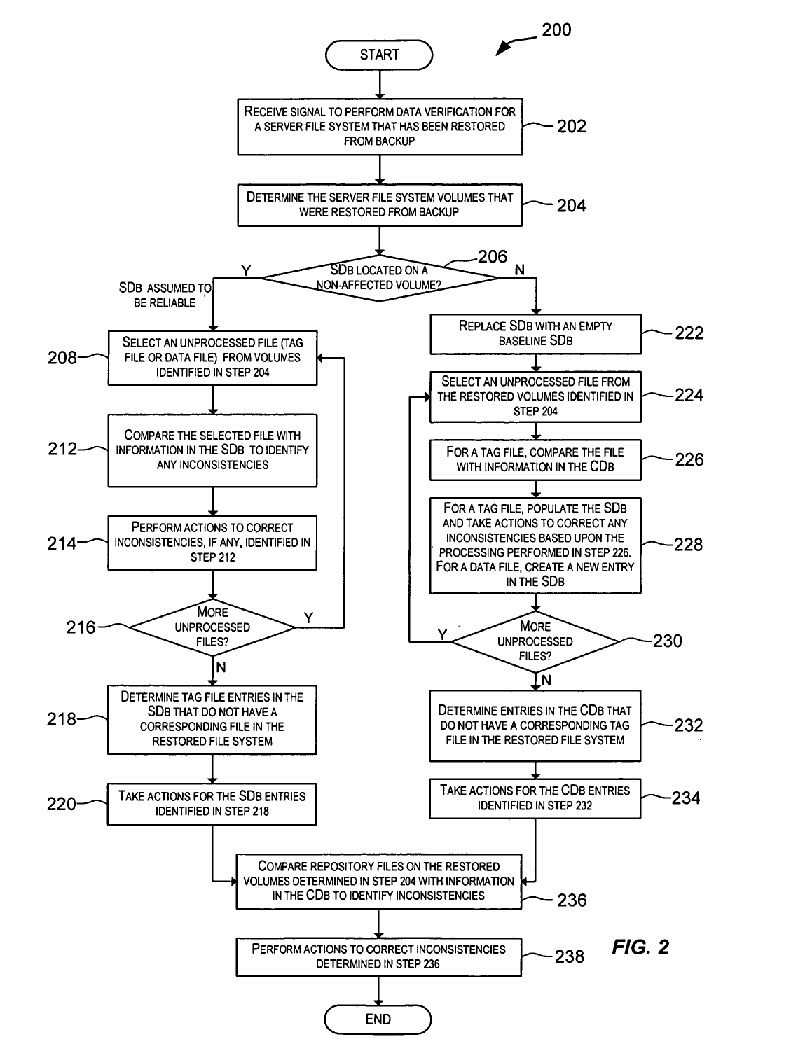

FIG. 2 is a simplified high-level flowchart 200 depicting a method of detecting and correcting or resolving inconsistencies in a restored file system according to an embodiment of the present invention. The method depicted in FIG. 2 may be performed by software modules executed by a processor, hardware modules, or combinations thereof. The processing may be performed by a server affected by the crash and whose file system has been restored. The processing may also be performed by SMS 110, or by SMS 110 in cooperation with other servers, or by a server 106. Flowchart 200 depicted in FIG. 2 is merely illustrative of an embodiment of the present invention and is not intended to limit the scope of the present invention. Other variations, modifications, and alternatives are also within the scope of the present invention. The method depicted in FIG. 2 may be adapted to work with different implementation constraints such as security constraints, operating system constraints, and the like.

As depicted in FIG. 2, processing is initiated upon receiving a signal to check data consistency (or data verification) for a server whose file system (or portion of the file system) has been restored (step 202). The signal may be received from various sources. In one embodiment, the process that restores the file system from backup may itself generate the signal to perform verification of data. A user such as an administrator of the storage system may also manually trigger generation of the signal to perform data verification.

The volumes of the server file system that were restored from backup are then determined (step 204). One or more volumes may be identified in step 204.

A check is then made to determine whether the SDb for the server is located on a non-affected volume (i.e., a volume that did not crash and was not restored from backup) (step 206). If it is determined that the SDb for the server is located on a non-affected volume, then the data stored in the SDb is assumed to be reliable and processing continues with step 208. If it is determined that the SDb for the server was partially or fully located on a non-affected volume, then the data stored in the SDb is assumed to be non-reliable and processing continues with step 222.

If the SDb data is determined to be reliable, each data file and tag file stored on the volumes determined in step 204 is compared with information in the SDb to identify and correct/resolve inconsistencies. As part of the processing, a previously unprocessed file (i.e., a data file or tag file that has not been processed according to steps 208, 212, 214, and 216) is selected from the one or more restored volumes identified in step 204 (step 208). The file is then compared with information stored in the SDb to identify any inconsistencies (step 212). An inconsistency occurs when the file information is inconsistent with the information stored in the SDb or the information stored in the SDb is not consistent with the file information.

Several different types of inconsistencies may be determined based upon the comparison performed in step 212. For example, an inconsistency may be identified in step 212 if the SDb does not comprise an entry corresponding to the selected file. Even if the SDb comprises an entry corresponding to the selected, an inconsistency may be identified if the SDb entry data is not consistent with the selected file data. For example, the selected file may be a tag file and the SDb entry may identify it as a data file, the selected file may be a data file and the SDb entry may identify it as a tag file, the file attributes information stored in the SDb entry for the file may not match the file attributes of the corresponding file, etc. Further details related to the types of inconsistencies that can be determined according to an embodiment of the present invention are provided below.

One or more actions are then automatically performed to correct/resolve inconsistencies, if any, identified in step 212 (step 214). Several different types of actions may be taken depending on the type of inconsistency including adding and/or modifying information stored in the SDb or CDb, deleting information from the SDb or CDb, deleting or modifying the selected file, etc. Further details related to the actions that may be performed according to an embodiment of the present invention are described below.

After the requisite actions to correct the inconsistency have been performed, a check is made to determine if there are any more unprocessed data or tag files (i.e., data or tag files that have not yet been compared to information in the SDb) stored on the restored volumes identified in step 204 (step 216). If more unprocessed data or tag files are detected, then processing continues with step 208 wherein another unprocessed file is selected for processing and steps 212, 214, and 216 are repeated. If it is determined in step 216 that there are no more unprocessed files (i.e., all the data and tag files stored on the restored volumes have been compared to the information stored in the SDb), then processing continues with step 218.

After all the tag and data files on the restored volumes have been compared with information stored in the SDb, tag file entries in the SDb that do not have corresponding files in the restored file system are determined (step 218). If such entries exist then they represent inconsistencies where there is no corresponding tag file for a tag entry in the SDb. One or more actions are then automatically performed to correct the inconsistencies determined in step 218 (step 220). Further details related to the processing performed in step 218 and 220 are provided below. Processing then continues with step 236.

Referring back to step 206, if it is determined that the SDb was partially or fully stored on an affected volume, then the data in the SDb is deemed to be unreliable. As a result, the existing SDb is replaced with a new empty baseline SDb (step 222). The new SDb is then populated and actions performed to correct any inconsistencies.

As part of the processing, a previously unprocessed file (i.e., a data file or tag file that has not been processed according to steps 224, 226, 228, and 230) is selected from the one or more restored volumes identified in step 204 (step 224). If the file selected in step 224 is a tag file, then the tag file is compared with corresponding information stored in the CDb to identify any inconsistencies (step 226). An inconsistency may occur if there is no record or entry of the tag file in the CDb. An inconsistency may also occur if a CDb entry exists for the tag file but CDb entry information is not consistent with the tag file information.

Information is then added to the SDb for the file selected in step 224 (step 228). If the selected file is a tag file, the information stored in the CDb for the tag file may be used to construct a new entry for the tag file in the SDb. One or more actions may also be performed to correct any inconsistencies determined in step 226. If the selected file is a data file, a new entry for the data file is created in the SDb. Further details related to the processing performed in steps 226 and 228 are provided below.

A check is then made to determine if there are more unprocessed data or tag files (step 230). If there are more unprocessed files, then processing continues with step 224 wherein another file is selected for processing. If all the tag and data files have been processed, then processing continues with step 232.

After all the tag and data files on the restored volumes have been processed according to steps 224, 226, 228, and 230, all entries in the CDb that do not have a corresponding tag file in the restored file system are determined (step 232). Inconsistencies are identified in step 232 where there is information stored in the CDb for a tag file but no corresponding tag file exists on the restored volumes. One or more actions are then automatically performed to correct the inconsistencies determined in step 232 (step 234). Processing then continues with step 236.

As described above, actions are performed in various steps (e.g., steps 214, 220, 228, and 234) to correct inconsistencies. As result of the actions, the information in the SDb and CDb is made consistent with the files in the restored file system.

The restored file system may also store repository files that have been restored from backup. These repository files represent data that has been migrated (or remigrated) from other servers. In one embodiment, the repository files are stored in a specific directory in the file system. These restored repository files that have been restored from backup may be inconsistent as they may not reflect migrations and remigrations that may have occurred after the backup was performed and before the file system crashed. Accordingly, after the data files and tag files have been processed as described above, the repository files stored on the restored volumes are compared with information in the CDb to identify any inconsistencies (step 236). One or more actions are then performed to correct any inconsistencies determined in step 236 (step 238). In this manner, inconsistencies associated with repository files are automatically detected and corrected.

In one embodiment, as depicted in FIG. 2, the repository files are processed after the tag and data files have been processed. In alternative embodiments, repository files processing may be done in parallel with or before processing of tag and data files.

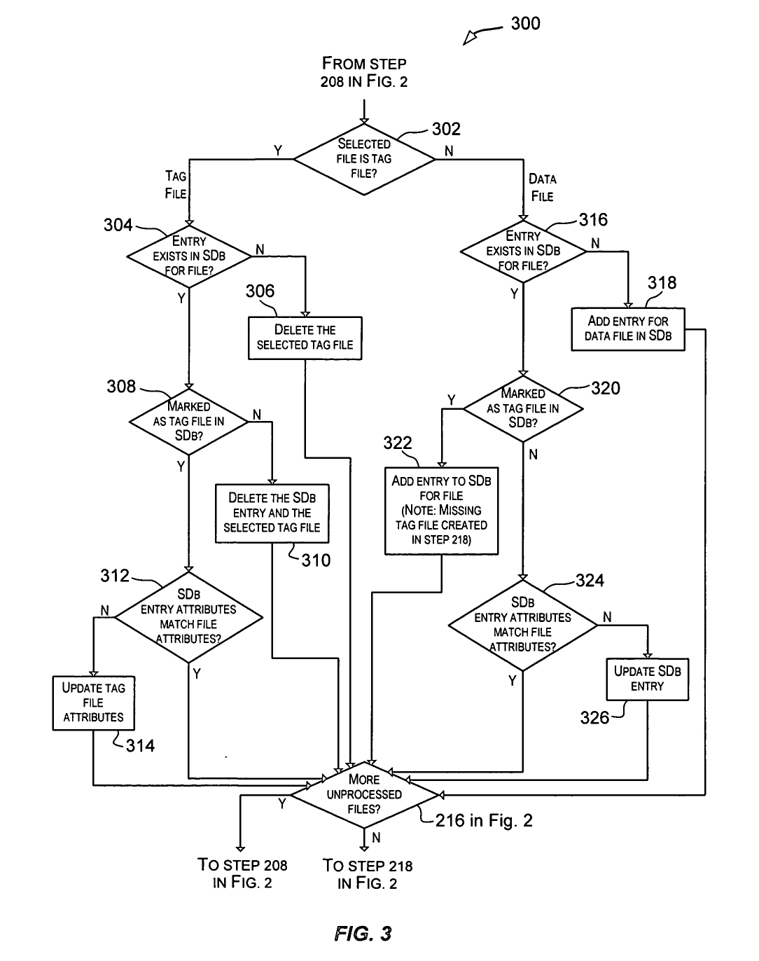

FIG. 3 is a simplified high-level flowchart 300 depicting a method of detecting and correcting tag files and data files-related inconsistencies in a restored file system according to an embodiment of the present invention. According to an embodiment of the present invention, the processing depicted in FIG. 3 is performed in steps 212, 214, and 216 of flowchart 200 depicted in FIG. 2. The method depicted in FIG. 3 may be performed by software modules executed by a processor, hardware modules, or combinations thereof. The processing may also be performed by SMS 110, or by SMS 110 in cooperation with other servers, or by a sever 106. Flowchart 300 depicted in FIG. 3 is merely illustrative of an embodiment of the present invention and is not intended to limit the scope of the present invention. Other variations, modifications, and alternatives are also within the scope of the present invention. The method depicted in FIG. 3 may be adapted to work with different implementation constraints such as security constraints, operating system constraints, and the like.

As depicted in FIG. 3, after an unprocessed file has been selected in step 208 of FIG. 2, a check is made to determine if the selected file is a tag file (step 302). If the file is a tag file then processing continues with step 304, else (file is a data file) processing continues with step 316.

If the file is determined to be a tag file in step 302, then a check is made to determine if an entry exists in the SDb for the tag file (step 304). If an entry corresponding to the tag file does not exist in the SDb, then the selected tag file is deleted (step 306). After deletion, processing continues with step 216 of FIG. 2.

If it is determined in step 304 that an entry corresponding to the tag file does exist in the SDb, then the SDb entry information is checked to see if the selected tag file is marked as a tag file (step 308). If the SDb entry information identifies the selected tag file as a data file rather than a tag file, this indicates an inconsistency and the SDb entry is deleted and the selected tag file is also deleted (step 310). After the deletion, processing continues with step 216 of FIG. 2.

If the SDb entry information correctly marks the selected tag file as a tag file, then the attributes of the selected tag file are compared with the attribute information in the SDb entry to see if it matches (step 312). If the tag file attributes information does not match the corresponding SDb entry attributes information, then the tag file is updated such that its attributes match the SDb entry attributes information (step 314). Attributes that may be compared and updated include size of the file, dates associated with the file, special tag file data (unique file identifier may be stored in the special tag file data), etc. Processing then continues with step 216 of FIG. 2. If the selected tag file attributes information matches the attributes information of the SDb entry, then no action is performed and processing continues with step 216 of FIG. 2.

Referring back to step 302, if the file is determined not to be a tag file (i.e., is determined to be a data file), then a check is made to determine if an entry exists in the SDb for the data file (step 316). If an entry corresponding to the data file does not exist in the SDb, then a new entry for the data file is created and added to the SDb (step 318). After the new entry is added, processing continues with step 216 of FIG. 2.

If it is determined in step 316 that an entry corresponding to the data file does exist in the SDb, then a check is made to determine if the SDb entry information marks the selected data file as a tag file (step 320). If the SDb entry information identifies the selected data file as a tag file rather than a data file, this indicates an inconsistency and a new entry is added to the SDb identifying the data file as a data file (step 322). Please note that the initial entry identifying the data file as a tag file is not deleted; it is used later in step 218 to create the missing tag file in the file system. After adding the new entry in step 322, processing continues with step 216 of FIG. 2.

If the SDb entry information correctly marks the selected data file as a data file, then the attributes of the selected data file are compared with the attribute information in the corresponding SDb entry to see if it matches (step 324). If the data file attributes information does not match the corresponding SDb entry attributes information, then the SDb entry information is updated to match the data file attributes information (step 326) and processing then continues with step 216 of FIG. 2. If the selected data file attributes information matches the attributes information of the SDb entry, then no action is performed and processing continues with step 216 of FIG. 2.

As previously described, in step 216 of FIG. 2, a check is made to determine if there are any more unprocessed data or tag files stored on the restored volumes. If more unprocessed data or tag files are detected then processing continues with step 208 in FIG. 2 and the processing depicted in FIG. 3 is repeated, else processing continues with step 218 in FIG. 2.

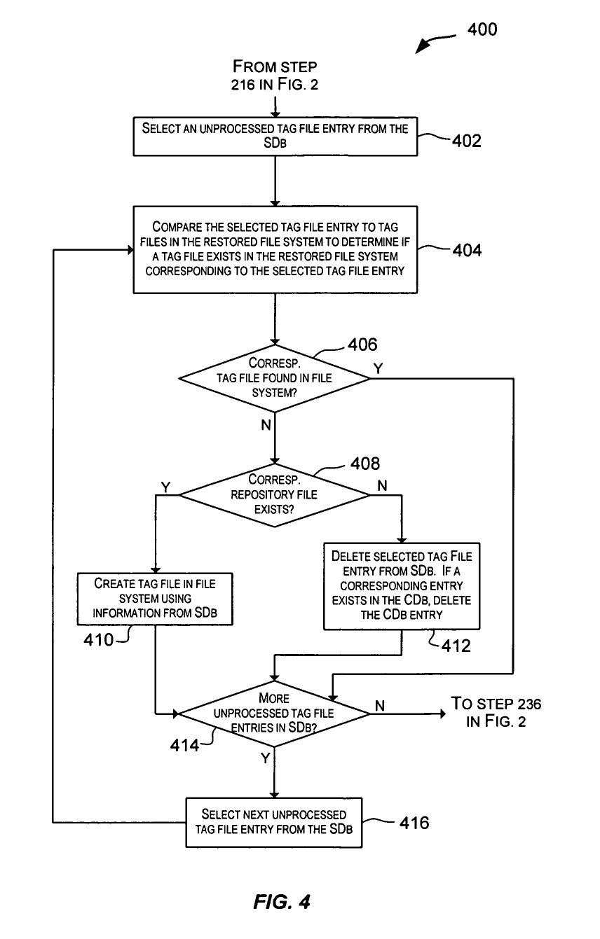

FIG. 4 is a simplified high-level flowchart 400 depicting a method of comparing SDb tag file entries to files in the file system and taking appropriate actions to correct any detected inconsistencies according to an embodiment of the present invention. According to an embodiment of the present invention, the processing depicted in FIG. 4 is performed in steps 218 and 220 of flowchart 200 depicted in FIG. 2. The method depicted in FIG. 4 may be performed by software modules executed by a processor, hardware modules, or combinations thereof. The processing may also be performed by SMS 110, or by SMS 110 in cooperation with other servers, or by a server 106. Flowchart 400 depicted in FIG. 4 is merely illustrative of an embodiment of the present invention and is not intended to limit the scope of the present invention. Other variations, modifications, and alternatives are also within the scope of the present invention. The method depicted in FIG. 4 may be adapted to work with different implementation constraints such as security constraints, operating system constraints, and the like.

As depicted in FIG. 4, an unprocessed tag file entry (i.e., an entry in the SDb marking a file as a tag file and that has not been processed according to flowchart 400 depicted in FIG. 4) is selected for processing (step 402). The selected tag file entry is then compared to tag files in the restored file system to determine if a tag file exists in the file system corresponding to the selected tag file entry (step 404). If a corresponding tag file is found in the restored file system corresponding to the selected SDb tag file entry (step 406), then processing continues with step 414.

If a corresponding tag file is not located in the file system for the selected tag file entry in step 406, then a check is made to determine if a repository file exists for the selected tag file entry (step 408). Information from the selected SDb tag file entry is used to determine if a repository file exists. If it is determined in step 408 that a corresponding repository file exists, then a new tag file is created using information from the selected tag file entry in the SDb (step 410). Processing then continues with step 414 after creating the tag file.

If it is determined in step 408 that a corresponding repository file does not exist, then the selected tag file entry is deleted from the SDb (step 412). If a corresponding entry exists in the CDb, then that CDb entry is also deleted in step 412. Processing then continues with step 414.

In step 414, a check is made to see if there are more unprocessed tag file entries in the SDb. If more entries exist, then the next unprocessed tag file entry is selected for processing (step 416). Processing from step 404 is then repeated for the selected tag file entry. If it is determined in step 414 that all tag file entries have been processed, then processing continues with step 236 depicted in FIG. 2.

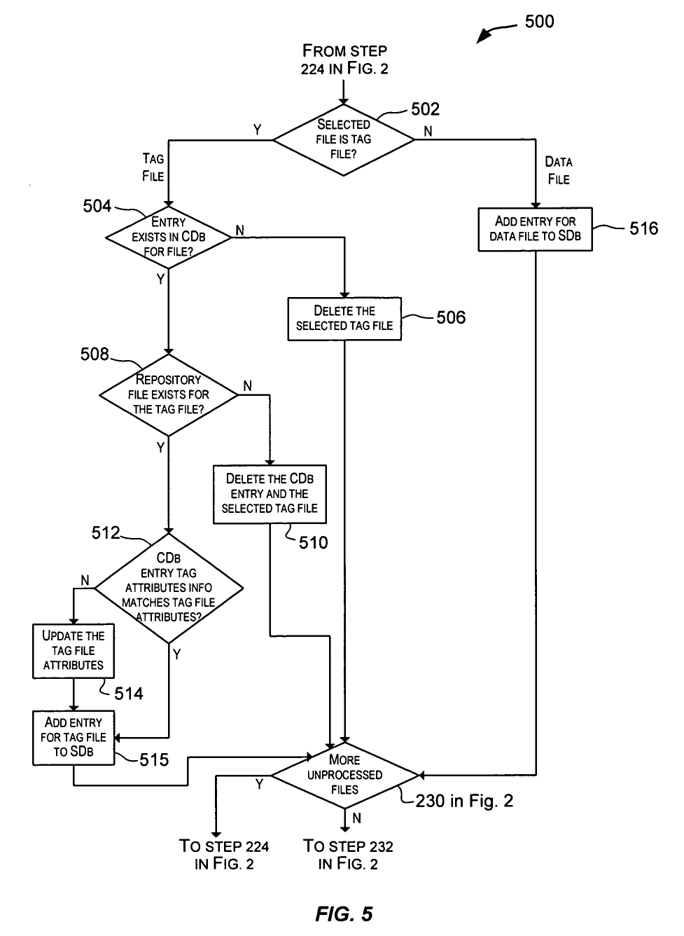

FIG. 5 is a simplified high-level flowchart 500 depicting a method of detecting and correcting tag files and data files related inconsistencies in a restored file system according to an embodiment of the present invention. According to an embodiment of the present invention, the processing depicted in FIG. 5 is performed in steps 226 and 228 of flowchart 200 depicted in FIG. 2. The method depicted in FIG. 5 may be performed by software modules executed by a processor, hardware modules, or combinations thereof. The processing may also be performed by SMS 110, or by SMS 110 in cooperation with other servers, or by a sever 106. Flowchart 500 depicted in FIG. 5 is merely illustrative of an embodiment of the present invention and is not intended to limit the scope of the present invention. Other variations, modifications, and alternatives are also within the scope of the present invention. The method depicted in FIG. 5 may be adapted to work with different implementation constraints such as security constraints, operating system constraints, and the like.

As depicted in FIG. 5, after an unprocessed file has been selected in step 224 of FIG. 2, a check is made to determine if the selected file is a tag file (step 502). If the file is a tag file then processing continues with step 504, else (file is a data file) processing continues with step 516.

If the file is determined to be a tag file in step 502, then a check is made to determine if an entry exists in the CDb for the tag file (step 504). If an entry corresponding to the tag file does not exist in the CDb, then the selected tag file is deleted (step 506). After deletion, processing continues with step 230 of FIG. 2.

If it is determined in step 504 that an entry corresponding to the tag file does exist in the CDb, then a check is made to determine if a repository file exists for the selected tag file (step 508). If it is determined in step 508 that a corresponding repository file does not exist for the tag file, then the CDb entry is deleted and the selected tag file is also deleted (step 510). After the deletion, processing continues with step 230 of FIG. 2.

If it is determined in step 508 that a repository file exists for the tag file, then the tag file attributes are compared with the attributes information in the CDb entry to see if there is a match (step 512). If the tag file attributes do not match the corresponding CDb entry tag attributes information, then the tag file is updated such that its attributes match the attributes information in the CDb entry (step 514). Attributes may be compared and corrected include file size, dates associated with the file, special tag file data (unique file identifier may be stored in the special tag file data), etc. Processing then continues with step 515. If the attributes of the selected tag file match the attributes information in the CDb entry, then processing continues with step 515.

In step 515, a new entry is created for the tag file in the SDb (step 515). Processing then continues with step 230 of FIG. 2.

Referring back to step 502, if the file is determined not to be a tag file (i.e., is determined to be a data file), then a new entry for the data file is created and added to the SDb (step 516). After the new entry is added, processing continues with step 230 of FIG. 2.

As previously described, in step 230 of FIG. 2, a check is made to determine if there are more unprocessed data or tag files. If there are more unprocessed files, then processing continues with step 224 wherein another file is selected for processing and the processing depicted in FIG. 5 is repeated. After all the tag and data files have been processed, then processing continues with step 232 in FIG. 2.

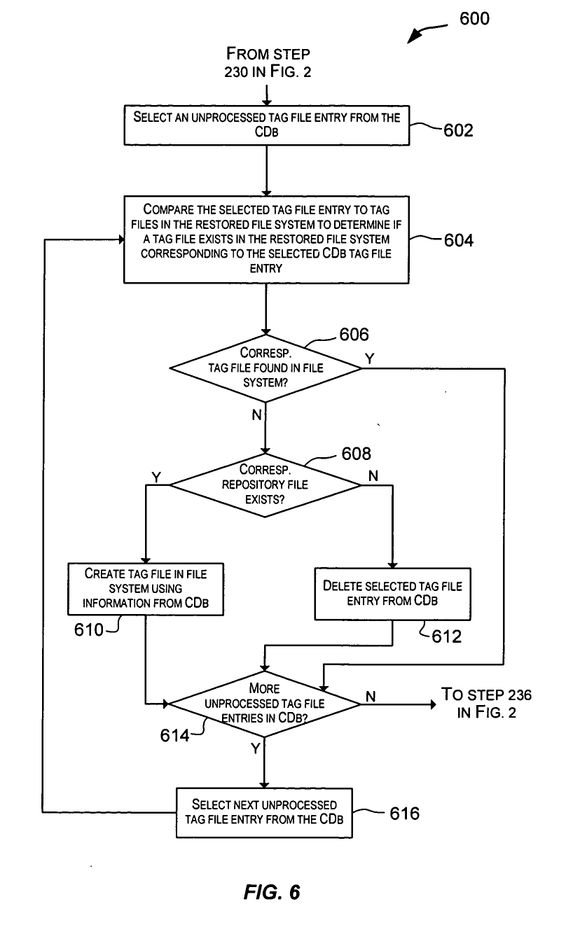

FIG. 6 is a simplified high-level flowchart 600 depicting a method of comparing CDb entries to files in the restored file system and taking appropriate actions to correct the detected inconsistencies according to an embodiment of the present invention. According to an embodiment of the present invention, the processing depicted in FIG. 6 is performed in steps 232 and 234 of flowchart 200 depicted in FIG. 2. The method depicted in FIG. 6 may be performed by software modules executed by a processor, hardware modules, or combinations thereof. The processing may also be performed by SMS 110, or by SMS 110 in cooperation with other servers, or by a server 106. Flowchart 600 depicted in FIG. 6 is merely illustrative of an embodiment of the present invention and is not intended to limit the scope of the present invention. Other variations, modifications, and alternatives are also within the scope of the present invention. The method depicted in FIG. 6 may be adapted to work with different implementation constraints such as security constraints, operating system constraints, and the like.

As depicted in FIG. 6, an unprocessed tag file entry from the CDb is selected for processing (step 602). The selected CDb tag file entry is then compared to tag files in the restored file system to determine if a tag file exists in the file system corresponding to the selected tag file entry (step 604). If a corresponding tag file is found in the restored file system corresponding to the selected CDb tag file entry (in step 606), then processing continues with step 614.

If a corresponding tag file is not located in the file system for the selected CDb tag file entry in step 606, then a check is made to determine if a repository file exists for the selected tag file entry (step 608). Information from the selected CDb tag file entry is used to determine if a repository file exists. If it is determined in step 608 that a corresponding repository file exists, then a new tag file is created using information from the selected CDb tag file entry (step 610). Processing then continues with step 614.

If it is determined in step 608 that a corresponding repository file does not exist, then the selected CDb tag file entry is deleted (step 612). Processing then continues with step 614.

In step 614, a check is made to see if there are more unprocessed tag file entries in the CDb (step 614). If more entries exist, then the next unprocessed tag file entry is selected for processing (step 616). Processing starting from step 604 is then repeated for the selected tag file entry. If it is determined in step 614 that all CDb tag file entries have been processed, then processing continues with step 236 depicted in FIG. 2.

As described above, embodiments of the present invention are able to automatically detect and correct various inconsistencies that may be present after restoration of data in a file system controlled by a storage application such as HSM. As a result of the processing performed according to an embodiment of the present invention, an originating server is restored to a consistent point-in-time image that is consistent with the backup image. The tag files on the originating server are rendered usable and loss of data is minimized. Information in the SDb and CDb is also updated to reflect the files in the restored file system.

According to an embodiment of the present invention, missing repository file can be identified by searching the CDb. The CDb stores a list of repository volumes, the originating servers, and the repository servers. In one embodiment, the repository files are stored in specific directories on the file systems of the various servers. The directory names identify the machine (machine id) the file came from and the name of the repository file (unique file identifier). In such an embodiment, missing repository files can be determined by comparing the repository information in the CDb to the repository directories of the servers. A repository entry in the CDb that does not have a matching entry a repository directory indicates either a missing repository file or an unsynchronized alternate recall condition. Some of the actions that may be performed to correct the inconsistencies are described below (see Table A).

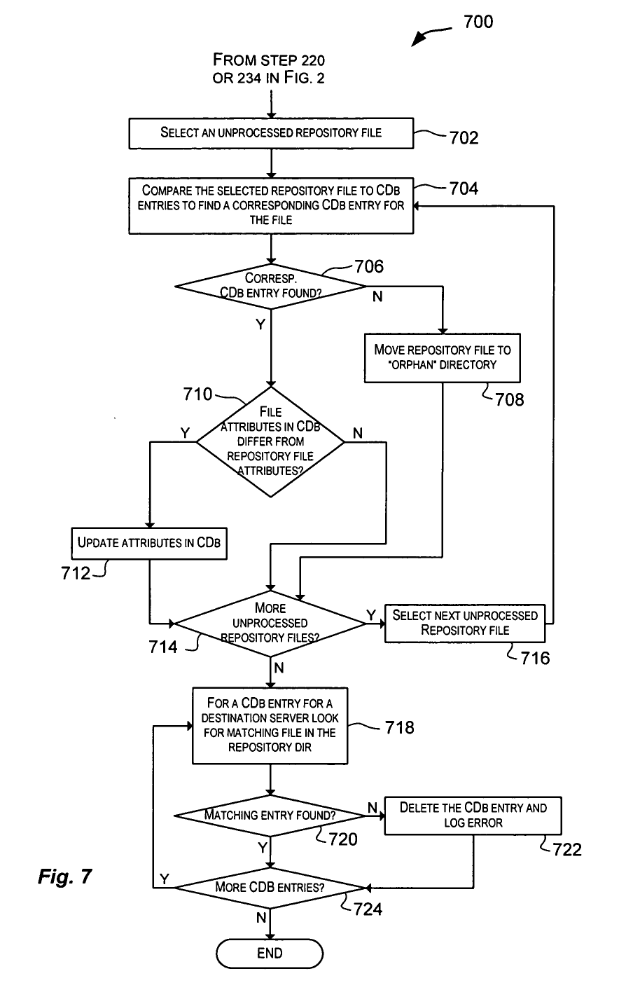

FIG. 7 is a simplified high-level flowchart 700 depicting a method of processing repository files in the restored file system according to an embodiment of the present invention. According to an embodiment of the present invention, the processing depicted in FIG. 7 is performed in steps 236 and 238 of flowchart 200 depicted in FIG. 2. The method depicted in FIG. 7 may be performed by software modules executed by a processor, hardware modules, or combinations thereof. The processing may also be performed by SMS 110, or by SMS 110 in cooperation with other servers, or by a server 106. Flowchart 700 depicted in FIG. 7 is merely illustrative of an embodiment of the present invention and is not intended to limit the scope of the present invention. Other variations, modifications, and alternatives are also within the scope of the present invention. The method depicted in FIG. 7 may be adapted to work with different implementation constraints such as security constraints, operating system constraints, and the like.

As depicted in FIG. 7, an unprocessed repository file (i.e., a repository file from the server's file system that has not been processed according to flowchart 700) is selected for processing (step 702). The selected repository file is then compared to information in the CDb to find a corresponding CDb entry for the repository file (step 704). According to an embodiment of the present invention, the unique file identifier of the selected repository file is used to determine if there is a corresponding entry in the CDb. A check is then made to determine if a corresponding CDb entry was found for the repository file (step 706).

If a corresponding CDb entry is not found, then the selected repository file is moved to a recovery area (step 708). According to an embodiment of the present invention, the repository file is moved to an “orphan” directory that stores repository files which do not have corresponding entries in the CDb. The file may subsequently be deleted or relocated from the orphan directory. Processing then continues with step 714.

If a corresponding CDb entry is found for the repository file, then a check is made to determine if the file attributes in the corresponding CDb entry differ from the attributes of the selected repository file (step 710). If the CDb entry file attributes differ, then the attributes information in the CDb entry is updated to match the repository file attributes (step 712). Processing then continues with step 714. If it is determined in step 710 that the attributes do not differ, then processing continues with step 714.

In step 714, a check is made to see if there are more unprocessed repository files (step 714). If more unprocessed repository files exist, then the next unprocessed repository file is selected (step 716) and processing starting from step 704 is then repeated for the selected repository file. If it is determined in step 714 that all repository files have been processed, then processing continues with step 718.

After all the repository files from the restored volumes have been compared to the CDb information, the CDb entries for the server are checked against the repository files stored on the server to determine if there exist any entries for which there are no corresponding repository files. According to an embodiment of the present invention, for each CDb entry for a destination server, a determination is made if there is a matching file in the repository directory of the server (step 718). If it is determined that a matching file is found (sep 720) then processing continues with step 724. If a matching file is not found, then the selected CDb entry for which there is no matching repository file is deleted (step 722). An error condition is also logged. Processing then continues with step 724.

In step 724, a check is made to determine if there are more CDb entries to be processed (step 714). If more unprocessed CDb entries exist, then processing continues with step 718, else the processing ends.

Table A shown below lists examples of inconsistencies that are detected by an embodiment of the present invention. The first column titled “Inconsistency” identifies the inconsistency. The column titled “Potential Cause” identifies potential conditions that may have caused the inconsistency. The column titled “Action Performed” identifies the actions that are taken to correct the inconsistency. Table A is not intended to be an exhaustive list of inconsistencies, potential causes, and actions performed. Embodiments of the present invention can also detect other types of inconsistencies and perform actions to correct the inconsistencies.

TABLE A

| | | |
|---|---|---|
| Inconsistency | Potential Causes | Action Performed |

Inconsistencies related to data files.

| | | |
|---|---|---|
| Specific cases related to data files: | | |
| (1) File system comprises a data | The data file was either renamed, | An entry is created in the SDb for |
| file after restoration from backup. | moved, or deleted after the backup. | the data file. |
| No entry for the data file in the | | |
| SDb. | | |
| (2) File system comprises a data | The data file was migrated after the | An entry is created in the SDb for |
| file after restoration from backup. | backup. After restoration, the tag | the data file. The missing tag file |
| SDb contains an entry for the file | file was replaced with the data file | is created corresponding to the SDb |
| but the entry marks the file as a tag | included in the backup. | entry information that marks the |
| file (i.e., as migrated). | | file as a tag file. |
| (3) File system comprises a data | The data file was modified after | The SDb entry attributes |
| file after restoration from backup. | backup. After restoration, an | information is updated to match the |
| SDb contains an entry for the file | “older” data file included in the | file attributes. If the entry is |
| that marks the file as a data file. | backup replaced the “newer” | marked as an unsynchronized |
| The SDb entry file attributes do not | modified data file. | alternate recall, then the CDb entry |
| match the file attributes of the | | corresponding to the file is deleted. |
| restored data file. | | |
| (4) File system comprises a data | The originating server was unable | CDb entry corresponding to the |
| file after restoration from backup. | to communicate with the CDb | data file is deleted. |
| SDb contains an entry for the file | when it recalled the file after | |
| that marks the status of the file as | backup. | |
| unsynchronized alternate recall. | | |

Inconsistencies related to tag files

Specific cases related to tag files:

| | | |
|---|---|---|
| (1) File system comprises a tag file | The migrated file corresponding to | The tag file is deleted and error |
| after restoration from backup. No | the tag file was either deleted, or | condition reported. |
| entry for the tag file in the SDb or | recalled and deleted after the | |
| CDb. | backup. | |
| (2a) File system comprises a tag | The SDb is lost. If the tag file | A new entry for the tag file is |
| file after restoration from backup. | attributes don't match, the tag file | added to the SDb. A check is made |
| The SDb information is lost. CDb | may have been recalled, modified | to determine if the tag file |
| contains a matching entry for the | and migrated again since the | attributes match the attributes |
| tag file. Repository file exists for | backup. | stored in the corresponding CDb |
| the tag file. | | entry. If the attributes do not |
| | | match, the tag file is modified to |
| | | make its attributes match the |
| | | attributes in the CDb entry. |
| (2b) File system comprises a tag | An alternate recall occurred after | The restored tag file is deleted. |
| file after restoration from backup. | the backup. After restoration from | The corresponding entry in the |
| SDb information is lost. CDb | backup, the data file was replaced | CDb is deleted. Error condition is |
| contains a matching entry for the | by the tag file from the backup. | reported that the data file has been |
| tag file. Repository file does not | (If the volume is lost, the data file | lost. Data may be retrieved from |
| exist for the tag file. | is gone and the backup contains the | an earlier backup before the file |
| | old tag file.) | was migrated. |
| (3) File system comprises a tag file | The file was recalled after the | The SDb entry and the tag file are |
| after restoration from backup. SDb | backup. The tag file was restored | deleted. An error is reported |
| contains an entry for the file but the | from backup overwriting the data | indicating loss of data file. |
| file is marked as a data file rather | file. | |
| than as a tag file. | | |
| (4) File system comprises a tag file | The file was recalled, modified, | The tag file attributes are updated |
| after restoration from backup. SDb | and migrated again after the | to match the SDb database. |
| contains an entry for the tag file but | backup. After restoration, the | |
| the attributes of the tag file do not | newer tag file was replaced by an | |
| match the attributes identified by | older version of the tag file. | |
| the SDb entry information.. | | |
| Missing tag file cases | | |
| (1) SDb comprises an entry for a | Repository file lost, tag created | The SDb entry is deleted. A |
| tag file. No corresponding tag file | after backup. | corresponding CDb entry exists, if |
| found in the restored file system. | | found, is also deleted. Report error |
| Corresponding repository file does | | condition that the data file is lost as |
| not exist. | | it was not contained in the backup. |
| | | The data file may be retrievable |
| | | from an earlier backup before the |
| | | file was migrated. |
| (2) SDb comprises an entry for a | A file was created and migrated | A new tag file is created using |
| tag file. No corresponding tag file | after the backup. | information from the SDb entry. |
| found in the restored file system. | | |
| Corresponding repository file | | |
| exists. | | |
| (3) SDb lost. CDb comprises an | An unsynchronized alternate recall | The CDb entry is deleted. Report |
| entry for a tag file. No | occurred after the backup. | error condition that the data file is |
| corresponding tag file found in the | Originating server could not inform | lost as it was not contained in the |
| restored file system. | the CDb of the recall before the | backup. The data file may be |
| Corresponding repository file does | data crash event. | retrievable from an earlier backup |
| not exist. | | before the file was migrated. |
| (4) SDb lost. CDb comprises an | Data file created after backup and | A new tag file is created using |
| entry for a tag file. No | migrated (creating tag). | information from the CDb entry. |
| corresponding tag file found in the | | |
| restored file system. | | |
| Corresponding repository file | | |
| exists. | | |

Inconsistencies related to repository files

| | | |
|---|---|---|
| (1) Repository file exists after | The file was possibly remigrated or | An error condition is reported |
| restoration. CDb contains an entry | changed since the last backup. An | indicating that the restored |
| for the repository file. The | older repository file was restored | repository file is older. Also report |
| repository file attributes differ from | from backup. | that updates performed to the file |
| the CDb entry attributes. | | since the backup may be lost. |
| (2) Repository file exists after | The file was either recalled or | The repository file is moved to a |
| restoration. CDb does not contain | deleted after the backup. | special “orphans” area for |
| an entry for the repository file. | | subsequent deletion or relocation. |
| | | An error condition is reported |
| | | indicating that the data file |
| | | corresponding to the repository file |
| | | is not accessible. |
| | | Such a repository file is called an |
| | | “orphan” referring to a valid |
| | | repository file with no tag file on |
| | | the originating server pointing to it. |
| (3) Volume of the repository file | The originating server machine was | An error condition is reported. The |
| does not exist in the CDb's volume | removed or uninstalled, or the | repository file is moved to a special |
| table. | HSM product was | “orphans” area for subsequent |
| | removed/uninstalled from the | deletion or relocation. |
| | originating server machine. | |
| (4) CDb contains an entry for a | The repository file was remigrated | An error condition is reported. The |
| repository file with no | after backup. Or, the backup | repository file is moved to a special |
| corresponding repository file (a | operation failed to archive the | “orphans” area for subsequent |
| different destination or repository | repository file. Or unsynchronized | deletion or relocation. |
| volume may be identified). | recall occurred. | |
| (5) Repository file missing. | Repository file was not included in | An error condition is reported |
| | the backup. | indicating that the repository file is |
| | | missing. |

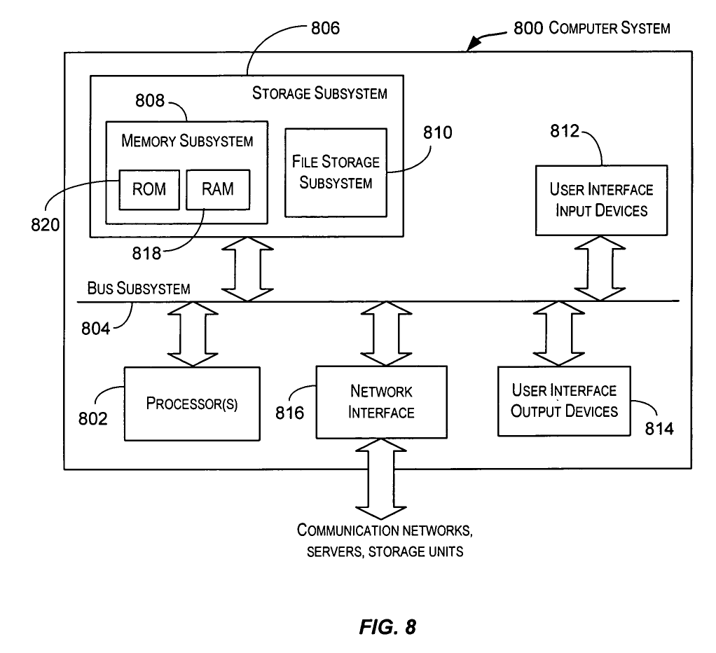

FIG. 8 is a simplified block diagram of a computer system 800 capable of implementing an embodiment of the present invention. As shown in FIG. 8, computer system 800 includes a processor 802 that communicates with a number of peripheral devices via a bus subsystem 804. These peripheral devices may include a storage subsystem 806, comprising a memory subsystem 808 and a file storage subsystem 810, user interface input devices 812, user interface output devices 814, and a network interface subsystem 816. The input and output devices allow a user, such as the administrator, to interact with computer system 800.

Network interface subsystem 816 provides an interface to other computer systems, networks, servers, and storage units. Network interface subsystem 816 serves as an interface for receiving data from other sources and for transmitting data to other sources from computer system 800. Embodiments of network interface subsystem 816 include an Ethernet card, a modem (telephone, satellite, cable, ISDN, etc.), (asynchronous) digital subscriber line (DSL) units, and the like.

User interface input devices 812 may include a keyboard, pointing devices such as a mouse, trackball, touchpad, or graphics tablet, a scanner, a barcode scanner, a touchscreen incorporated into the display, audio input devices such as voice recognition systems, microphones, and other types of input devices. In general, use of the term “input device” is intended to include all possible types of devices and mechanisms for inputting information to computer system 800.

User interface output devices 814 may include a display subsystem, a printer, a fax machine, or non-visual displays such as audio output devices, etc. The display subsystem may be a cathode ray tube (CRT), a flat-panel device such as a liquid crystal display (LCD), or a projection device. In general, use of the term “output device” is intended to include all possible types of devices and mechanisms for outputting information from computer system 800.

Storage subsystem 806 may be configured to store the basic programming and data constructs that provide the functionality of the present invention. For example, according to an embodiment of the present invention, software code modules implementing the functionality of the present invention may be stored in storage subsystem 806. These software modules may be executed by processor(s) 802. Storage subsystem 806 may also provide a repository for storing data used in accordance with the present invention. For example, the SDb and CDb databases may be stored in storage subsystem 806. Storage subsystem 806 may also be used as a migration repository to store data that is moved from a storage unit. Storage subsystem 806 may also be used to store data that is moved from another storage unit. Storage subsystem 806 may comprise memory subsystem 808 and file/disk storage subsystem 810.

Memory subsystem 808 may include a number of memories including a main random access memory (RAM) 818 for storage of instructions and data during program execution and a read only memory (ROM) 820 in which fixed instructions are stored. File storage subsystem 810 provides persistent (non-volatile) storage for program and data files, and may include a hard disk drive, a floppy disk drive along with associated removable media, a Compact Disk Read Only Memory (CD-ROM) drive, an optical drive, removable media cartridges, and other like storage media.

Bus subsystem 804 provides a mechanism for letting the various components and subsystems of computer system 800 communicate with each other as intended. Although bus subsystem 804 is shown schematically as a single bus, alternative embodiments of the bus subsystem may utilize multiple busses.

Computer system 800 can be of various types including a personal computer, a portable computer, a workstation, a network computer, a mainframe, a kiosk, or any other data processing system. Due to the ever-changing nature of computers and networks, the description of computer system 800 depicted in FIG. 8 is intended only as a specific example for purposes of illustrating the preferred embodiment of the computer system. Many other configurations having more or fewer components than the system depicted in FIG. 8 are possible.

Although specific embodiments of the invention have been described, various modifications, alterations, alternative constructions, and equivalents are also encompassed within the scope of the invention. The described invention is not restricted to operation within certain specific data processing environments, but is free to operate within a plurality of data processing environments. Additionally, although the present invention has been described using a particular series of transactions and steps, it should be apparent to those skilled in the art that the scope of the present invention is not limited to the described series of transactions and steps.

Further, while the present invention has been described using a particular combination of hardware and software, it should be recognized that other combinations of hardware and software are also within the scope of the present invention. The present invention may be implemented only in hardware, or only in software, or using combinations thereof.

The specification and drawings are, accordingly, to be regarded in an illustrative rather than a restrictive sense. It will, however, be evident that additions, subtractions, deletions, and other modifications and changes may be made thereunto without departing from the broader spirit and scope of the invention as set forth in the claims.

What is claimed is:

1. In a storage environment comprising a plurality of servers, the plurality of servers including a first server having a file system storing a plurality of files restored from a backup medium, the plurality of files including one or more data files and one or more tag files corresponding to data files that have migrated from the file system, a computer-implemented method of maintaining consistency of the file system of the first server, the method comprising:
providing first information comprising information related to the plurality of files stored in the file system of the first server, the first information comprising a plurality of entries, each entry corresponding to a file and storing status information identifying whether the file is a tag file or a data file, each entry storing attributes information identifying one or more attributes of the file;
comparing the plurality of files to information included in the first information;
identifying, based upon the comparing, at least a first inconsistency where information associated with a first file from the plurality of files is inconsistent with information in the first information; and
performing a first set of one or more operations to resolve the first inconsistency.

2. The method of claim 1 further comprising:
identifying at least a first entry in the first information that stores status information identifying a file as a tag file and for which there is no corresponding tag file in the plurality of files; and
performing a second set of one or more operations for the first entry.

3. The method of claim 2 wherein performing the second set of one or more operations comprises:
determining, based upon information in the first entry, if a repository file exists corresponding to the first entry; and
deleting the first entry from the first information upon determining that a repository file corresponding to the first entry does not exist.

4. The method of claim 2 wherein performing the second set of one or more operations comprises:
determining, based upon information in the first entry, if a repository file exists corresponding to the first entry; and
creating a tag file using information in the first entry upon determining that a repository file corresponding to the first entry exists.

5. The method of claim 2 wherein the plurality of files comprises one or more repository files storing migrated data, the method further comprising:
providing second information including information related to files stored by the plurality of servers that have been migrated;
comparing the one or more repository files to information stored in the first information and the second information;
identifying at least one inconsistency based upon comparing the one or more repository files to information in the first information and the second information; and
performing a set of one or more actions to resolve the at least one inconsistency.

6. The method of claim 1 wherein:
the first file is a tag file representing a data file that has been migrated from the file system of the first server;
identifying at least a first inconsistency comprises determining that the first information does not include an entry for the first file; and
performing the first set of one or more operations comprises deleting the first file.

7. The method of claim 1 wherein:
the first file is a tag file representing a data file that has been migrated from the file system of the first server;
identifying at least a first inconsistency comprises determining that the first information includes an entry corresponding to the first file storing status information that identifies the file as a data file; and
performing the first set of one or more operations comprises:
deleting the first file; and
deleting the entry in the first information corresponding to the first file.

8. The method of claim 1 wherein:
the first file is a tag file representing a data file that has been migrated from the file system of the first server;
identifying at least a first inconsistency comprises determining that the first information includes an entry corresponding to the first file storing status information that identifies the file as a tag file, wherein the attributes information stored by the entry does not match at least one attribute of the first file; and
performing the first set of one or more operations comprises updating the first file such that the at least one attribute of the first file matches the attributes information stored in the entry in the first information corresponding to the first file.

9. The method of claim 1 wherein:
the first file is a data file;
identifying at least a first inconsistency comprises determining that the first information does not include an entry for the first file; and
performing a first set of one or more operations comprises adding an entry to the first information for the first file.

10. The method of claim 1 wherein:
the first file is a data file;
identifying at least a first inconsistency comprises determining that the first information includes a first entry corresponding to the first file storing status information that identifies the file as a tag file; and
performing the first set of one or more operations comprises:
adding a second entry to the first information for the first file; and
creating a tag file to corresponding to the information in the first entry in the first information.

11. The method of claim 1 wherein:
the first file is a data file;
identifying at least a first inconsistency comprises determining that the first information includes an entry corresponding to the first file storing status information that identifies the file as a data file, wherein the attributes information stored by the entry does not match at least one attribute of the first file; and
performing the first set of one or more operations comprises updating the information in the first information entry corresponding first file such that the attributes information stored in the entry matches the at least one attribute of the first file.

12. In a storage environment comprising a plurality of servers, the plurality of servers including a first server having a file system storing a plurality of files restored from a backup medium, the plurality of files including one or more data files and one or more tag files corresponding to data files that have migrated from the file system, a computer-implemented method of maintaining consistency of the file system of the first server, the method comprising:
providing first information including information related to files stored in the file system of the first server;
providing second information comprising a plurality of entries, each entry storing information related a file stored by the plurality of servers that has been migrated;
comparing a first tag file from the plurality of files to information stored in the second information;
identifying, based upon the comparing, at least a first inconsistency where information associated with the first tag file is inconsistent with the information included in the second information; and
performing a first set of one or more actions to resolve the first inconsistency.

13. The method of claim 12 wherein:
identifying the first inconsistency comprises determining that the second information does not include an entry for the first tag file; and
performing the first set of one or more actions comprises deleting the first tag file.

14. The method of claim 12 wherein:
identifying the first inconsistency comprises determining that the second information includes a first entry for the first tag file, a repository file exists for the first tag file, and information in the first entry does not match at least one attribute of the first tag file; and
performing the first set of one or more actions comprises:
updating the first tag file such that the at least one attribute of the first tag file matches the information in the first entry; and
adding an entry to the first information for the first tag file, the entry storing information related to the first tag file.

15. The method of claim 12 wherein:
identifying the first inconsistency comprises determining that the second information includes a first entry for the first tag file, a repository file exists for the first tag file, and information in the first entry matches one or more attributes of the first tag file; and
performing the first set of one or more actions comprises adding an entry to the first information for the first tag file, the entry storing information related to the first tag file.

16. The method of claim 12 further comprising:
identifying at least a first entry in the second information for which there is no corresponding tag file in the plurality of files; and
performing a second set of one or more operations for the first entry.

17. The method of claim 16 wherein performing the second set of one or more operations comprises:
determining, based upon information in the first entry in the second information, if a repository file exists corresponding to the first entry; and
deleting the first entry from the second information upon determining that a repository file corresponding to the first entry does not exist.

18. The method of claim 16 wherein performing the second set of one or more operations comprises:
determining, based upon information in the first entry, if a repository file exists corresponding to the first entry; and
creating a tag file using information in the first entry for the second information upon determining that a repository file corresponding to the first entry exists.

19. In a storage environment managed by a hierarchical storage management application comprising a plurality of servers, the plurality of servers including a first server having a file system storing a plurality of files including one or more data files and one or more tag files corresponding to data files that have migrated from the file system, a computer-implemented method of recovering information, the method comprising:
providing first information including information related to one or more data files that have been migrated, wherein the information related to each data file that has been migrated includes information identifying a server and a volume from which the data file is migrated, and information identifying a server and volume where the migrated data of the data file is stored, the first information comprising information related to a first data file that has been migrated;
determining, based upon the first information, that the file system does not contain a tag file corresponding to first data file; and
creating a tag file corresponding to the first data file based upon information included in the first information.

20. In a storage environment comprising a plurality of servers, the plurality of servers including a first server having a file system storing a plurality of files restored from a backup medium, the plurality of files including one or more data files and one or more tag files corresponding to data files that have migrated from the file system, a computer program product stored on a computer-readable medium for maintaining consistency of the file system of the first server, the computer program product comprising:
code for providing first information comprising information related to the plurality of files stored in the file system of the first server, the first information comprising a plurality of entries, each entry corresponding to a file and storing status information identifying whether the file is a tag file or a data file, each entry storing attributes information identifying one or more attributes of the file;
code for comparing the plurality of files to information included in the first information;
code for identifying, based upon the comparison, at least a first inconsistency where information associated with a first file from the plurality of files is inconsistent with information in the first information; and
code for performing a first set of one or more operations to resolve the first inconsistency.

21. The computer program product of claim 20 further comprising:
code for identifying at least a first entry in the first information that stores status information identifying a file as a tag file and for which there is no corresponding tag file in the plurality of files; and
code for performing a second set of one or more operations for the first entry.

22. The computer program product of claim 21 wherein the code for performing the second set of one or more operations comprises:
code for determining, based upon information in the first entry, if a repository file exists corresponding to the first entry; and
code for deleting the first entry from the first information upon determining that a repository file corresponding to the first entry does not exist.

23. The computer program product of claim 21 wherein the code for performing the second set of one or more operations comprises:
code for determining, based upon information in the first entry, if a repository file exists corresponding to the first entry; and
code for creating a tag file using information in the first entry upon determining that a repository file corresponding to the first entry exists.

24. The computer program product of claim 21 wherein the plurality of files comprises one or more repository files storing migrated data, the computer program product further comprising:
code for providing second information including information related to files stored by the plurality of servers that have been migrated;
code for comparing the one or more repository files to information stored in the first information and the second information;
code for identifying at least one inconsistency based upon comparing the one or more repository files to information in the first information and the second information; and
code for performing a set of one or more actions to resolve the at least one inconsistency.

25. The computer program product of claim 20 wherein:
the first file is a tag file representing a data file that has been migrated from the file system of the first server;
the code for identifying at least a first inconsistency comprises code for determining that the first information does not include an entry for the first file; and
the code for performing the first set of one or more operations comprises code for deleting the first file.

26. The computer program product of claim 20 wherein:
the first file is a tag file representing a data file that has been migrated from the file system of the first server;
the code for identifying at least a first inconsistency comprises code for determining that the first information includes an entry corresponding to the first file storing status information that identifies the file as a data file; and
the code for performing the first set of one or more operations comprises:
code for deleting the first file; and
code for deleting the entry in the first information corresponding to the first file.

27. The computer program product of claim 20 wherein:
the first file is a tag file representing a data file that has been migrated from the file system of the first server;
the code for identifying at least a first inconsistency comprises code for determining that the first information includes an entry corresponding to the first file storing status information that identifies the file as a tag file, wherein the attributes information stored by the entry does not match at least one attribute of the first file; and
the code for performing the first set of one or more operations comprises code for updating the first file such that the at least one attribute of the first file matches the attributes information stored in the entry in the first information corresponding to the first file.

28. The computer program product of claim 20 wherein:
the first file is a data file;
the code for identifying at least a first inconsistency comprises code for determining that the first information does not include an entry for the first file; and
the code for performing a first set of one or more operations comprises code for adding an entry to the first information for the first file.

29. The computer program product of claim 20 wherein:
the first file is a data file;
the code for identifying at least a first inconsistency comprises code for determining that the first information includes a first entry corresponding to the first file storing status information that identifies the file as a tag file; and
the code for performing the first set of one or more operations comprises:
code for adding a second entry to the first information for the first file; and
code for creating a tag file to corresponding to the information in the first entry in the first information.

30. The computer program product of claim 20 wherein:
the first file is a data file;
the code for identifying at least a first inconsistency comprises code for determining that the first information includes an entry corresponding to the first file storing status information that identifies the file as a data file, wherein the attributes information stored by the entry does not match at least one attribute of the first file; and
the code for performing the first set of one or more operations comprises code for updating the information in the first information entry corresponding first file such that the attributes information stored in the entry matches the at least one attribute of the first file.

31. In a storage environment comprising a plurality of servers, the plurality of servers including a first server having a file system storing a plurality of files restored from a backup medium, the plurality of files including one or more data files and one or more tag files corresponding to data files that have migrated from the file system, a computer program product stored on a computer-readable medium for maintaining consistency of the file system of the first server, the computer program product comprising:
code for providing first information including information related to files stored in the file system of the first server;
code for providing second information comprising a plurality of entries, each entry storing information related a file stored by the plurality of servers that has been migrated;
code for comparing a first tag file from the plurality of files to information stored in the second information;
code for identifying, based upon the comparing, at least a first inconsistency where information associated with the first tag file is inconsistent with the information included in the second information; and
code for performing a first set of one or more actions to resolve the first inconsistency.

32. The computer program product of claim 31 wherein:
the code for identifying the first inconsistency comprises code for determining that the second information does not include an entry for the first tag file; and
code for performing the first set of one or more actions comprises code for deleting the first tag file.

33. The computer program product of claim 31 wherein:
the code for identifying the first inconsistency comprises code for determining that the second information includes a first entry for the first tag file, a repository file exists for the first tag file, and information in the first entry does not match at least one attribute of the first tag file; and
the code for performing the first set of one or more actions comprises:
code for updating the first tag file such that the at least one attribute of the first tag file matches the information in the first entry; and
code for adding an entry to the first information for the first tag file, the entry storing information related to the first tag file.

34. The computer program product of claim 31 wherein:
the code for identifying the first inconsistency comprises code for determining that the second information includes a first entry for the first tag file, a repository file exists for the first tag file, and information in the first entry matches one or more attributes of the first tag file; and
the code for performing the first set of one or more actions comprises code for adding an entry to the first information for the first tag file, the entry storing information related to the first tag file.

35. The computer program product of claim 31 further comprising:
code for identifying at least a first entry in the second information for which there is no corresponding tag file in the plurality of files; and
code for performing a second set of one or more operations for the first entry.

36. The computer program product of claim 35 wherein the code for performing the second set of one or more operations comprises:
code for determining, based upon information in the first entry in the second information, if a repository file exists corresponding to the first entry; and
code for deleting the first entry from the second information upon determining that a repository file corresponding to the first entry does not exist.

37. The computer program product of claim 35 wherein the code for performing the second set of one or more operations comprises:
code for determining, based upon information in the first entry, if a repository file exists corresponding to the first entry; and
code for creating a tag file using information in the first entry for the second information upon determining that a repository file corresponding to the first entry exists.

38. In a hierarchical storage management environment comprising a plurality of servers, the plurality of servers including a first server having a file system storing a plurality of files including one or more data files and one or more tag files corresponding to data files that have migrated from the file system, a computer program product stored on a computer-readable medium for recovering information, the computer program product comprising:
code for providing first information including information related to one or more data files that have been migrated, wherein the information related to each data file that has been migrated includes information identifying a server and a volume from which the data file is migrated, and information identifying a server and volume where the migrated data of the data file is stored, the first information comprising information related to a first data file that has been migrated;
code for determining, based upon the first information, that the file system does not contain a tag file corresponding to first data file; and
code for creating a tag file corresponding to the first data file based upon information included in the first information.

39. A storage system managed using a hierarchical storage management application, the storage system comprising:
a first server; and
a set of one or more storage units coupled to the first server, the set of storage units storing a plurality of files restored from a backup medium, the plurality of files including one or more data files and one or more tag files corresponding to data files that have migrated from the set of storage units;
a memory configured to store first information comprising information related to the plurality of files stored on the set of storage units, the first information comprising a plurality of entries, each entry corresponding to a file, each entry storing status information identifying whether the file is a tag file or a data file, each entry storing attributes information identifying one or more attributes of the file;
wherein the first server is configured to
compare the plurality of files to information included in the first information,
identify, based upon the comparison, at least a first inconsistency where information associated with a first file from the plurality of files is inconsistent with information in the first information, and
perform a first set of one or more operations to resolve the first inconsistency.

40. A storage system managed using a hierarchical storage management application, the storage system comprising:
a first server; and
a set of one or more storage units coupled to the first server, the set of storage units storing a plurality of files restored from a backup medium, the plurality of files including one or more data files and one or more tag files corresponding to data files that have migrated from the set of storage units; and
a memory configured to store first information and second information, the first information including information related to files stored by the set of storage units, the second information storing information for one or more files stored by the set of storage units that have been migrated;
wherein the first server is configured to
compare a first tag file from the plurality of files to information stored in the second information,
identify, based upon the comparing, at least a first inconsistency where information associated with the first tag file is inconsistent with the information included in the second information, and
perform a first set of one or more actions to resolve the first inconsistency.

41. In a storage system managed by a hierarchical storage management application, the storage system comprising a plurality of servers, the plurality of servers including a first server having a file system storing a plurality of files including one or more data files and one or more tag files corresponding to data files that have migrated from the file system, a data processing system comprising:
a processor; and
a memory configured to store first information including information related to one or more data files that have been migrated, wherein the information related to each data file that has been migrated includes information identifying a server and a volume from which the data file is migrated, and information identifying a server and volume where the migrated data of the data file is stored, the first information comprising information related to a first data file that has been migrated, the memory further configured to store a plurality of instructions which when executed by the processor cause the processor to:
determine, based upon the first information, that the file system does not contain a tag file corresponding to first data file; and
create a tag file corresponding to the first data file based upon information included in the first information.
